(19) United States
(12) Patent Application Publication
(10) Pub. No.: US 2012/0231553 A1
(43) Pub. Date: Sep. 13, 2012

(54) SUBSTRATE PROCESSING APPARATUS AND FABRICATION PROCESS OF A SEMICONDUCTOR DEVICE

(75) Inventors: Yoichi OKITA, Kawasaki (JP); Koji IBI, Shimonoseki (JP); Minoru Suzuki, Kasugai (JP); Yuuichi Tachino, Ichinomiya (JP)

(73) Assignee: FUJITSU SEMICONDUCTOR LIMITED, Yokohama-shi (JP)

(21) Appl. No.: 13/479,496

(22) Filed: May 24, 2012

Related U.S. Application Data
(62) Division of application No. 11/491,544, filed on Jul. 24, 2006.
Application No. 11/491,544 is a continuation of application No. PCT/JP2004/004602, filed on Mar. 31, 2004.

(51) Int. Cl. H01L 21/311; H01L 21/3065

(52) U.S. Cl. 438/3; 156/345.33; 257/E21.249

(57) ABSTRACT

A substrate processing apparatus includes a processing vessel evacuated by an evacuation system and including therein a stage for holding thereon a substrate to be processed, the processing vessel defining therein a processing space, a processing gas supply path that introduces an etching gas into the processing vessel, a plasma source that forms plasma in the processing space, and a high-frequency source connected to the stage. The processing vessel includes therein a shielding plate dividing the processing space into a first processing space part including a surface of the substrate to be processed and a second processing space part corresponding to a remaining part of the processing space, wherein the shielding plate is formed with an opening having a size larger than a size of the substrate to be processed.

### CROSS-REFERENCE TO RELATED APPLICATION

The present invention is a divisional of application Ser. No. 11/491,544, filed Jul. 24, 2006, which is a continuation application filed under 35 U.S.C. 111 (a) claiming benefit under 35 U.S.C. 120 and 365(c) of PCT application JP2004/004602 filed on Mar. 31, 2004, the entire contents of each are incorporated herein as reference.

### BACKGROUND OF THE INVENTION

The present invention generally relates to etching technology and more particularly to an etching apparatus used for fabrication of semiconductor devices.

Plasma etching is an indispensable technology in the production of semiconductor devices, and various etching apparatuses including parallel-plate etching apparatus are used for fabrication of general semiconductor devices.

In the fabrication process of conventional semiconductor devices, etching technology is used for patterning insulation films primarily formed of SiO₂ or patterning metal films such as Al, W, Ti, or the like.

On the other hand, in the fabrication of those semiconductor devices such as recent ferroelectric memory devices (FeRAMs) having a ferroelectric film or high-K dielectric film of PZT(Pb(Zr,Ti)O₃), PLZT ((Pb,La)(Zr,Ti)O₃), BST (BiSrTiO₃), STO (SrTiO₃), and the like, and further having an electrode film of a metallic material of low vapor pressure such as Pt, Ir and Ru, and the like, there is a need of high electron density and electron energy (electron temperature) for etching these films, and thus, there is a need of using a high density plasma etching apparatus such as ECR apparatus, helicon apparatus, ICP (induction coupling) apparatus, and the like. Particularly, an ICP etching apparatus is used extensively because of relatively simple construction of the apparatus.

FIGS. 1A-1D show a part of the fabrication process of a conventional FeRAM, particularly the fabrication process of a ferroelectric capacitor used therein.

Referring to FIG. 1A, there is formed an insulation film 2 on a silicon substrate 1 so as to cover a memory cell transistor formed on the silicon substrate 1 but not illustrated, and a lower electrode layer 3 of a precious metal such as Pt or a conductive oxide such as IrO₂, SrRuO₃, or the like, is formed on the insulation film 2 via an adhesive layer such as Ti (not illustrated). Further, a ferroelectric film 4 such as PZT (Pb(Zr,Ti)O₃), is formed on the lower electrode 3, and an upper electrode layer of a precious metal of Pt, Ir, Ru, or the like, or a conductive oxide such as IrO₂ or SrRuO₃ is formed on the ferroelectric film 4.

Next, in the process of FIG. 1B, the upper electrode layer 5 is patterned by a photolithographic process, and with this, an upper electrode 5A is formed on the ferroelectric film 4.

In the step of FIG. 1B, oxygen defects formed in the ferroelectric film 4 at the time of the patterning of the upper electrode layer 5 is compensated for by a thermal annealing process conducted in an oxygen ambient, and the ferroelectric film 4 is patterned by the photolithographic process in the step of FIG. 1C. With this, a ferroelectric capacitor insulation film 4A is formed on the lower electrode layer 3.

In the step of FIG. 1C, the ferroelectric capacitor insulation film 4A thus formed is further annealed in an oxidizing ambient, and oxygen defects formed in the ferroelectric capacitor insulation film 4A at the time of the patterning of the ferroelectric film 4 are compensated. Further, the upper electrode 5A and the ferroelectric capacitor insulation film 4A are covered by a first encap layer 6 of Al₂O₃, or the like, that functions as a barrier against penetration of hydrogen.

Further, in the step of FIG. 1D, a lower electrode 3A is formed by patterning the lower electrode layer 3 and further the Ti adhesive layer provided underneath by a photolithographic process.

Further, in the step of FIG. 1D, a second encap layer 7 of Al₂O₃, or the like, is formed so as to cover the ferroelectric capacitor thus formed via the first encap layer 6.

In such fabrication process of FeRAM, a plasma etching process has been used in the photolithographic process that patterns the lower electrode layer 3, the ferroelectric film 4 and the upper electrode layer 5, while these films contain metallic elements of low vapor pressure, and because of this, no sufficient etching rate is obtained when the etching is conducted with the radicals formed by plasma excitation alone. Thus, there is a need of using a high density plasma etching process in which sputtering is caused in addition to the radical etching reaction.

FIG. 2 shows the construction of an ICP etching apparatus 10 used conventionally with the high density plasma etching process of FIGS. 1B-1D.

Referring to FIG. 2, the ICP etching apparatus 10 includes a quartz bell jar 11 evacuated at an evacuation port 10A as a processing vessel, wherein the processing vessel 11 defines a processing space 11A, and a stage 15 holding thereon a substrate W to be processed is provided inside the processing vessel 11. Further, a coil 12 is wound around the processing vessel 11 as antenna.

The coil 12 is connected to a high frequency power supply 14 via an impedance matching circuit 13, and plasma is formed in the processing vessel 11 by introducing a plasma gas such as Ar into the processing vessel 11 from a plasma gas supply port 11a and further by supplying a high frequency electric power to the coil 12 from the high frequency power supply 14. Thus, by introducing an etching gas containing halogen such as Cl or F into the processing vessel 11 from a processing gas inlet port 11b, for example, there is caused excitation of radicals of the etching gas at the surface of the substrate to be processed with the plasma.

Further, the stage 15 is connected to a high frequency bias power supply 18 via a blocking capacitor 16 and an impedance matching circuit 17, and a negative bias potential is applied to the stage 15 by supplying thereto a high frequency bias power from the high frequency bias power supply 18.

As a result of application of the bias potential, the positive ions in the plasma such as Ar+ cause collision with the substrate on the stage 15 together with radicals formed in the plasma, and sputtering is caused at the same time to etching. Thereby, efficient anisotropic etching process acting generally perpendicularly to the substrate to be processed is attained.
Patent Reference 1 Japanese Laid-Open Patent Application 2000-195841 official gazette
Patent Reference 2 Japanese Laid-Open Patent Application 57-96528 official gazette Patent Reference 3 Japanese Laid-Open Patent Application 58-168230 official gazette
Patent Reference 4 Japanese Laid-Open Patent Application 6-333881 official gazette
Patent Reference 5 Japanese Laid-Open Patent Application 6-243993 official gazette
Patent Reference 6 Japanese Laid-Open Patent Application 10-163180 official gazette

### SUMMARY OF THE INVENTION

However, when a plasma etching process that causes sputtering is applied to a substrate to be processed, there arises a problem in that particles sputtered out from the substrate to be processed as a result of the sputtering action as shown in FIG. 3 tend to cause deposition on the inner wall surface of the processing vessel 11. In the case of using a high density plasma etching apparatus for the fabrication of semiconductor devices having a ferroelectric capacitor such as FeRAM explained with reference to FIGS. 1A-1D, especially, there is a tendency that deposition of precious metal films of low vapor pressure such as Pt, Ir, Ru, or the like, takes place.

In the case of the ICP plasma etching apparatus 10 of FIG. 2, the high frequency power from the coil 12 no longer reaches the processing space 11A inside the processing vessel 11 when deposition of such conductive film takes place on the inner wall surface of the processing vessel 11, and the plasma etching becomes no longer possible. Further, production yield of the semiconductor device decreases seriously when such deposits on the inner wall surface of the processing vessel 11 have caused separation.

In the plasma etching of ordinary SiO₂-base insulation films or metal films such as Al, W, Ti, and the like, it is possible to remove the deposits effectively even when such deposits are caused on the inner wall surface of the processing vessel 11, by supplying a cleaning gas to the processing vessel 11 and by causing plasma excitation in the processing vessel by supplying the high frequency power from the high-frequency source 14. In the plasma etching process of recent low-K dielectric interlayer insulation films of these days, too, it is possible to remove the deposits such as hydrocarbons adhered to the inner wall surface of the processing vessel 11 effectively by inducing oxygen plasma in the processing vessel by way of supplying an oxidation gas such as an oxygen gas to the processing vessel 11 and further driving the high frequency coil 12 with high frequency power of the high-frequency source 14.

In the case of production of a semiconductor device such as FeRAM that includes a material of low vapor pressure and thus of low etching rate, there are often the case in which the deposits adhered to the inner wall surface of the processing vessel 11 are formed of the material of low vapor pressure such as precious metal. Because of this, the foregoing plasma cleaning process is not effective, and there has been the need of conducting a wet cleaning process for the processing vessel 11 frequently by dismantling the plasma etching apparatus 10 in order to conduct the plasma etching process with high yield and high efficiency. However, such frequent maintenance causes decrease of production efficiency of the semiconductor device.

According to an aspect of the present invention, there is provided a substrate processing apparatus, comprising:

a processing vessel evacuated by an evacuation system and including therein a stage for holding thereon a substrate to be processed, said processing vessel defining therein a processing space;

a processing gas supply path that introduces an etching gas into said processing vessel;

a plasma source that forms plasma in said processing space; and

a high-frequency source connected to said stage,

said processing vessel including therein a shielding plate dividing said processing space into a first processing space part including a surface of said substrate to be processed and a second processing space part corresponding to a remaining part of said processing space,

wherein said shielding plate is formed with an opening having a size larger than a size of said substrate to be processed.

According to the present invention, the particles emitted from the substrate held on the stage of a high density plasma processing due to the sputtering action associated with plasma etching at the time of applying such plasma etching to the substrate are captured effectively by the shielding plate, and formation of deposits on the inner wall surface of the processing vessel is suppressed. Because the shielding plate has the opening with a size exceeding the size of the substrate to be processed, there occurs no falling of the deposits on the substrate to be processed from the shielding plate even when the deposits on the shielding plate have been separated. Thus, it becomes possible with the present invention to avoid decrease of production yield of the semiconductor device by using the shielding plate. Further, by forming the opening in the shielding plate with the size exceeding the size of the substrate to be processed, it becomes possible to carry out uniform plasma etching over the entire substrate surface.

Other objects and further features of the present invention will become apparent from the following detailed description when read in conjunction with the attached drawings.

### BRIEF DESCRIPTION OF THE DRAWINGS

FIGS. 1A-1D are diagrams showing the fabrication process of a conventional ferroelectric capacitor;

FIG. 2 is a diagram showing the construction of a conventional ICP high density plasma etching apparatus;

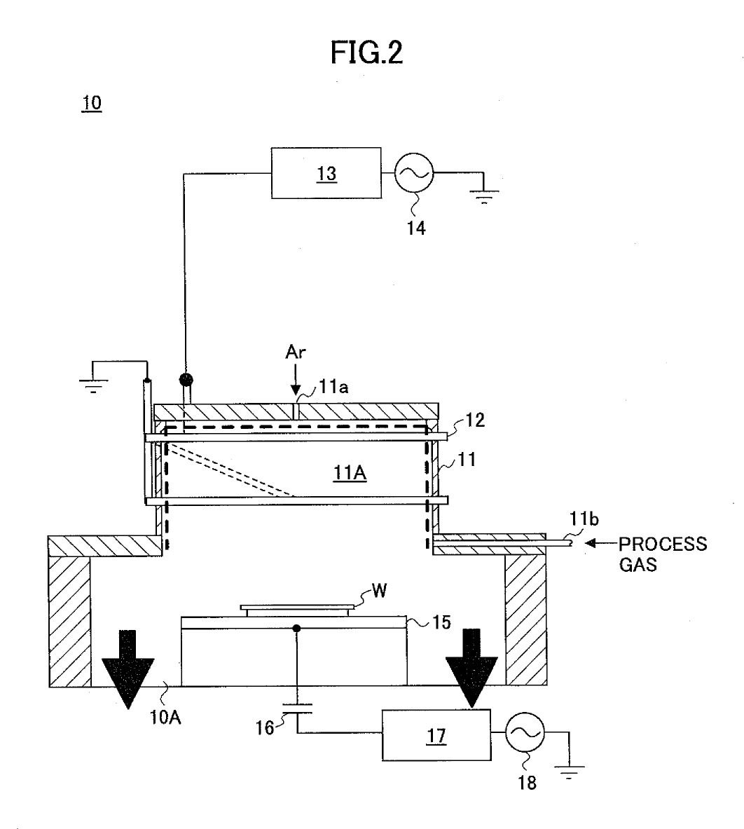

FIG. 3 is a diagram explaining the problem of the plasma etching apparatus of FIG. 2;

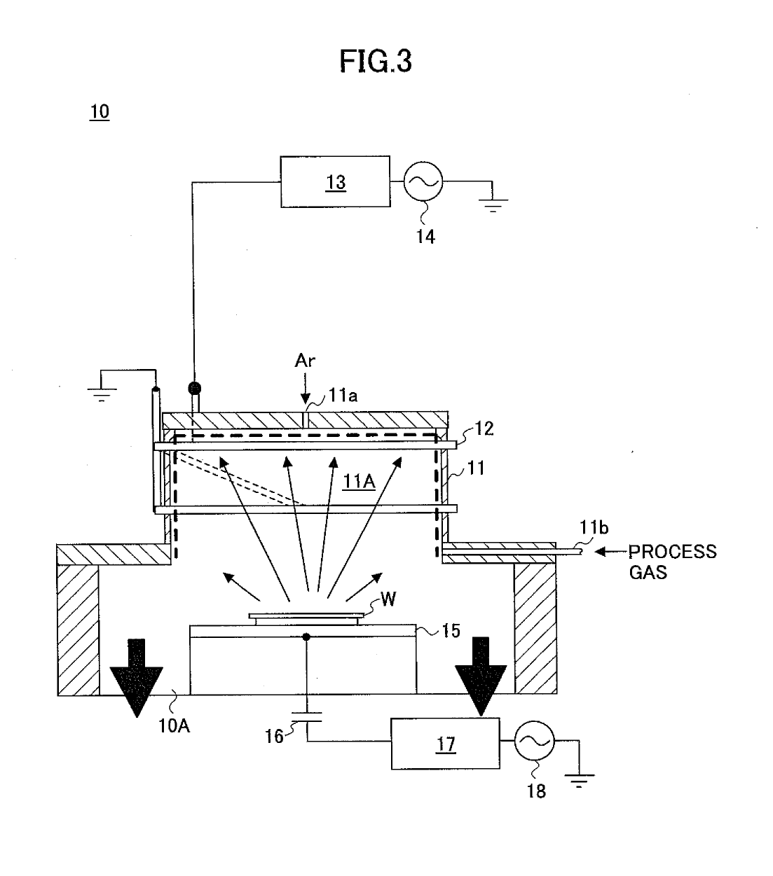

FIG. 4 is a diagram showing the construction of a plasma etching apparatus according to a first embodiment of the present invention;

FIG. 5 is a diagram showing the construction of a shielding plate used with the plasma etching apparatus of FIG. 4;

FIG. 6 is a diagram showing a modification of the shielding plate of FIG. 5;

FIG. 7 is a diagram showing the construction of a plasma etching apparatus according to a second embodiment of the present invention;

FIG. 8 is a diagram showing a modification of the plasma etching apparatus of FIG. 7;

FIG. 9 is a diagram showing the construction of the plasma etching apparatus of the first embodiment of the present invention;

FIG. 10 is a diagram showing the construction of a plasma etching apparatus according to a third embodiment of the present invention.

### DETAILED DESCRIPTION OF THE INVENTION

### First Embodiment

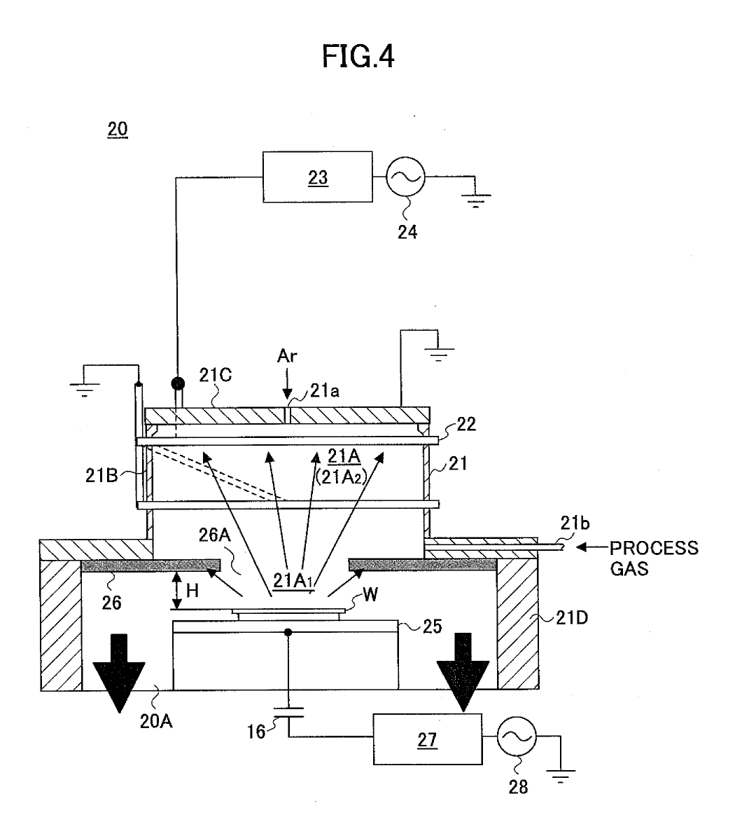

FIG. 4 shows the construction of a plasma etching apparatus 20 according to a first embodiment of the present invention.

Referring to FIG. 4, the plasma etching apparatus 20 is an ICP etching apparatus and includes a quartz bell jar 21 evacuated at an evacuation port 20A and defining a processing space 21A as a processing vessel, and a stage 25 is provided inside the processing vessel 21 for holding thereon a substrate to be processed horizontally. Further, a coil 22 is wound around the processing vessel 21 as antenna. The processing vessel 21 is formed of: a sidewall part 21B of quartz glass sleeve defining the processing space 21A; a metal cover lid 21C formed on the quartz sidewall part 21B and closing the processing space 21A at the top part thereof; a main part 21D that encloses the stage 25 in the lower part of the quartz sidewall part 21B and supports the quartz sidewall part 21B; and an evacuation port 20A for evacuating the interior of the processing vessel 21.

The coil 22 is connected to a high frequency power supply 24 through an impedance matching circuit 23, and plasma is formed in the processing vessel 21 by introducing a plasma gas such as He, Ne, Ar, Kr, Xe, and the like, into the processing vessel 21 from a plasma gas supply port 21a formed in the metal lid 21C and by supplying a high frequency electric power to the coil 22 from the high frequency power supply 24. Thus, by introducing an etching gas containing halogen such as Cl or F, the examples of which being Cl₂, CCl₄, CHF₃, and the like, into the processing vessel 21 from a processing gas inlet port 21b provided to the main part 21D, for example, there is caused radicals of the etching gas at the surface of the substrate to be processed as a result of excitation by the plasma.

Further, the stage 25 is connected to a high frequency bias power supply 28 via the blocking capacitor 16 and an impedance matching circuit 27, and a negative bias potential is applied to the stage 25 by supplying a high frequency bias power from the high frequency bias power supply 28.

As a result of application of the bias potential, the positive ions in the plasma such as Ar+ cause collision with the substrate to be processed on the stage 25 together with radicals formed in the plasma, and sputtering is caused at the same time to etching. Thereby, efficient anisotropic etching process acting generally perpendicularly to the substrate W is attained.

With the ICP plasma etching apparatus 20 of FIG. 4, there is formed a shielding plate 26 of an insulator such as quartz or alumina so as to cover the substrate W for capturing the sputter particles emitted from the substrate W with the sputtering action and so as to minimize the formation of deposits on the inner wall of the processing vessel 21. Thus, the shielding plate 26 divides the processing space 21A inside the processing vessel 21 into a processing space part 21A₁, in which the substrate surface is included and in which the etching and sputtering take place, and a processing space part 21A₂, in which the high density plasma is excited by being supplied with the high frequency power from the coil 21. In the shielding plate 26, there is formed an opening 26A having a diameter larger than the diameter of the substrate W.

With the plasma etching apparatus 20 of FIG. 4, the radicals and ions of the etching gas excited in the processing space 21A₂ reach the surface of the substrate W through the opening 26A formed in the shielding plate 26, and uniform and efficient etching is performed over the entire substrate surface.

Further, the particles sputtered out from the substrate as a result of collision of ions associated with the plasma etching and thus have scattered to the sidewall surface of the processing vessel 21 are captured by the shielding plate 26, and there is caused no formation of deposits on the sidewall surface of the processing vessel 21.

Further, because the opening 26A is formed in the shielding plate 26 directly over the substrate W with a diameter larger than the diameter of the substrate W with the plasma etching apparatus 20 of FIG. 4, there is caused no falling of the deposits from the shielding plate 26 upon the surface of substrate to be processed W, even in the case there has been caused separation of the deposits from the shielding plate 26, and it becomes possible to avoid the degradation of production yield of the semiconductor device.

Particularly, in the case the substrate W is a wafer of the diameter of 15-20 cm, it becomes possible to reduce the probability that the deposits separated from the shielding plate 26 fall upon the surface of the substrate W by falling along an irregular path, by setting the opening 26A to be larger than the wafer diameter by 0.5-5 cm.

In the case of conducting an etching process with the plasma etching apparatus 20 of FIG. 4, it becomes possible with the present embodiment to achieve a high etching rate by grounding the metal cover 21C provided on the quartz sidewall part 21B. By doing so, the negative bias voltage applied to the substrate W from the high frequency power supply 28 via the stage 25 works effectively. At the same time, there is caused reverse sputtering with such a construction in the sputter particles that have caused deposition on the lower surface of the metal lid 21C through the opening 26A, by the charged particles newly coming in through the opening 26A, and thus, there is caused little formation of deposits in the part of the processing vessel 21 located directly over the substrate W. Thus, with such a construction, there is formed no thick deposits on the part the lower surface of the metal lid 21C locating right above the substrate W. Thus, even when the opening 26A exposes the substrate W, there is little concern that the deposits may fall upon the substrate W from the metal lid 21C through the opening 26A.

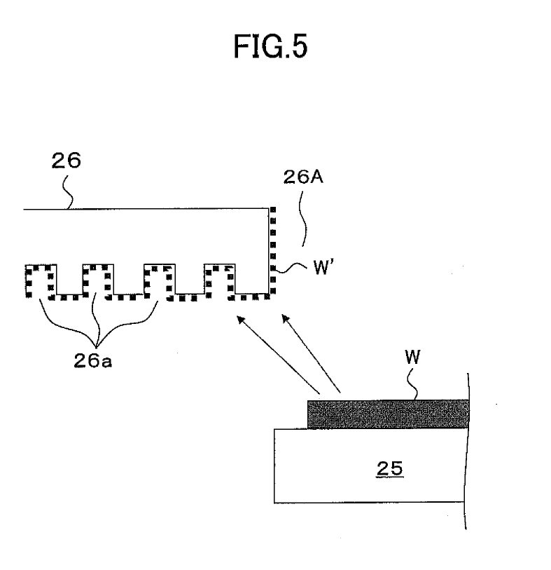

FIG. 5 shows the details of the shielding plate 26.

Referring to FIG. 5, there are formed minute projections and depressions 26a on the bottom surface of the shielding plate 26 by sand blast processing, and the like, with a pitch of approximately 0.1-several millimeters.

By forming such projections and depressions 26a, it becomes possible to increase the surface area of the shielding plate 26 at the bottom surface thereof, and the deposits W′ sputtered from the surface of the substrate W are captured effectively by the projections and depressions 26a. Further, because of increase in the surface area of the shielding plate 26 at the bottom surface with such a construction, it becomes possible to reduce the thickness of deposits W′ per unit area.

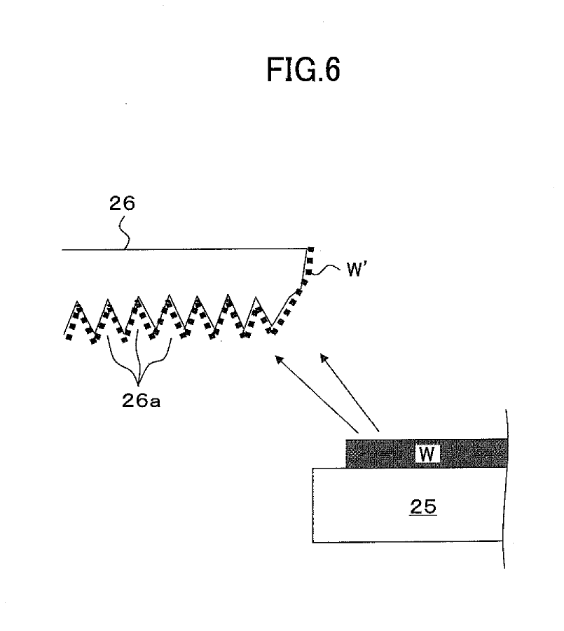

While FIG. 5 shows the projections and depressions to have a rectangular cross-section, it should be noted that FIG. 5 is a mere schematic illustration, and there may be formed a saw-tooth cross-section or irregular cross-section as represented in FIG. 6.

Because the substrate W is held horizontally on the stage 25, loading and unloading of substrate is conducted easily with the plasma processing apparatus 20 of FIG. 4. Further, a preferable effect of reducing the contamination of the substrate W with the falling impurities from the upward direction is obtained.

### Second Embodiment

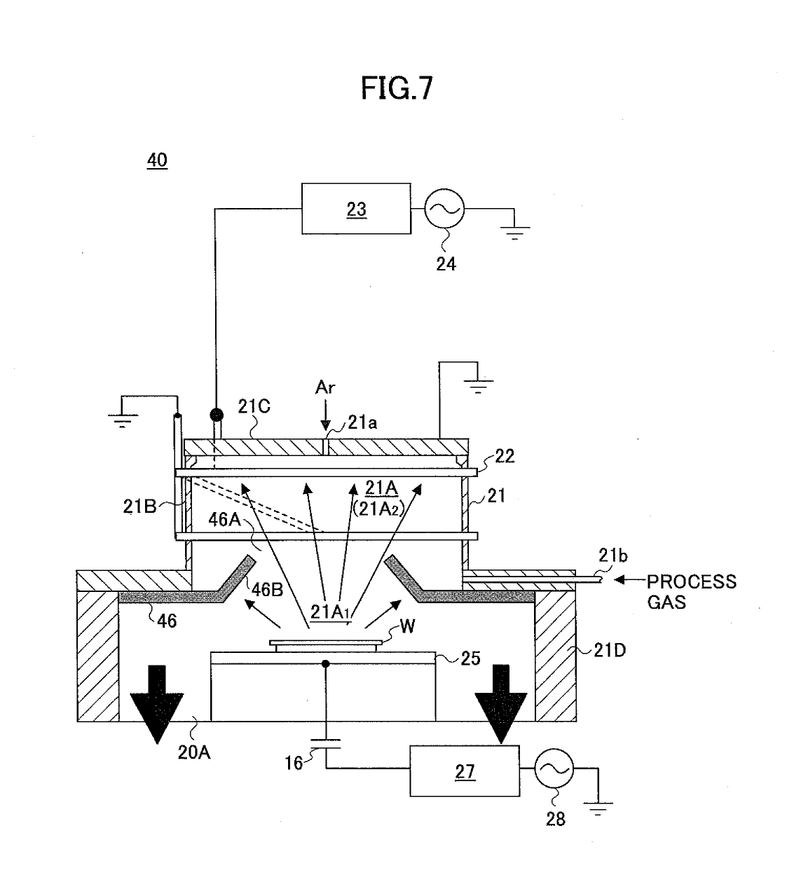

FIG. 7 shows the construction of a plasma etching apparatus 40 according to a second embodiment of the present invention, wherein those parts of FIG. 7 corresponding to those parts explained previously are designated with the same reference numerals and the description thereof will be omitted.

Referring to FIG. 7, the plasma etching apparatus 40 has a construction similar to that of the plasma etching apparatus 20 of FIG. 4, except that there is provided a shielding plate 46 in place of the shielding plate 26.

Similarly to the shielding plate 26, the shielding plate 46 has an opening 46A larger than the diameter of the substrate W, wherein it will be noted that the inner edge of the shielding plate 46 that includes the opening 46A forms a sloped surface forming a warp in the upward direction at a part 46B near the center of the opening 46A.

By forming such a sloped surface 46B warping in the upward direction in the shielding plate 46 with the plasma etching apparatus 40 of FIG. 7, there is caused an increase of capturing area of the sputter particles emitted from the substrate W, and it becomes possible to achieve more effective suppressing of deposition of the sputter particles on the quartz sidewall part 21B and elimination of particles caused by coming off of the deposits. Further, by forming such a sloped surface 46B, it becomes possible to prevent falling of the deposits upon the surface of the substrate W through the opening 46A, even in the case the deposits has fallen upon the shielding plate 46.

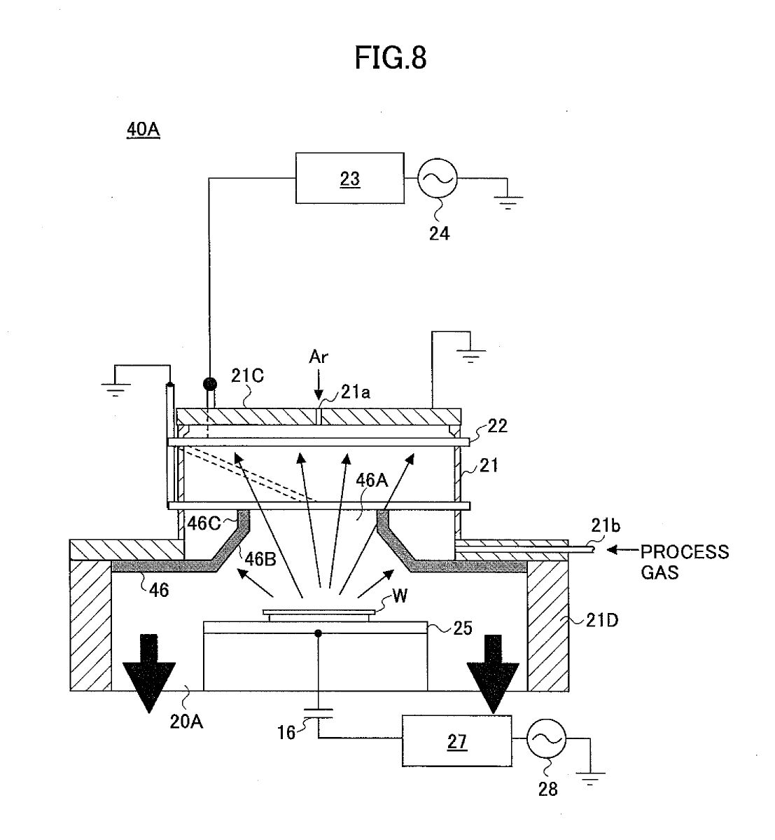

FIG. 8 shows the construction of a plasma etching apparatus 40A according to a modification of the plasma etching apparatus 40 of FIG. 7, wherein those parts of FIG. 8 corresponding to the parts explained previously are designated by the same reference numerals and the description thereof will be omitted.

Referring to FIG. 8, it can be seen that there is formed an extension part 46C extending in the upward direction at the inner edge of the sloped surface 46B so as to define the opening 46A with the plasma etching apparatus 40A. By forming such an extension part 46C, the capturing area of the sputter particles is increased further, and it becomes possible to prevent the falling of the deposits, came off and falling upon the shielding plate 46, further upon the surface of the substrate W.

### Third Embodiment

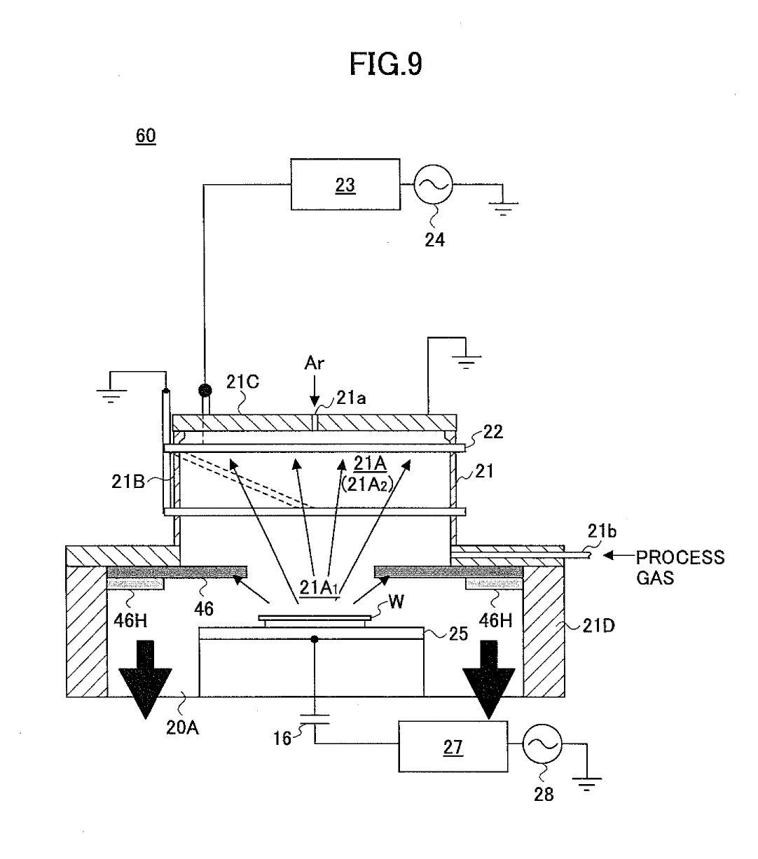

FIG. 9 shows the construction of a plasma etching apparatus 60 according to a third embodiment of the present invention, wherein those parts of FIG. 9 corresponding to those parts explained previously are designated with the same reference numerals and the description thereof will be omitted.

Referring to FIG. 9, the plasma etching apparatus 60 has a construction similar to that of the plasma etching apparatus 20 of FIG. 4, except that there is provided a temperature control unit 46H such as heater on a part of the shielding plate 46 for controlling the temperature of the shielding plate 46.

The temperature control unit 46H maintains the temperature of the shielding plate 46 constantly to 200° C. including loading and unloading of the substrate W, and with this, it becomes possible to avoid the problem that the temperature of the shielding plate 46 drops at the time of exchanging the substrate W and there is caused coming off of the deposits captured on the shielding plate 46 due to the difference of thermal expansion coefficient. Thereby, the problem of the deposits thus came off falling upon the substrate W is eliminated.

It should be noted that such a temperature adjustment part 46H may be provided to any of the embodiments explained previously or to be explained below.

### Fourth Embodiment

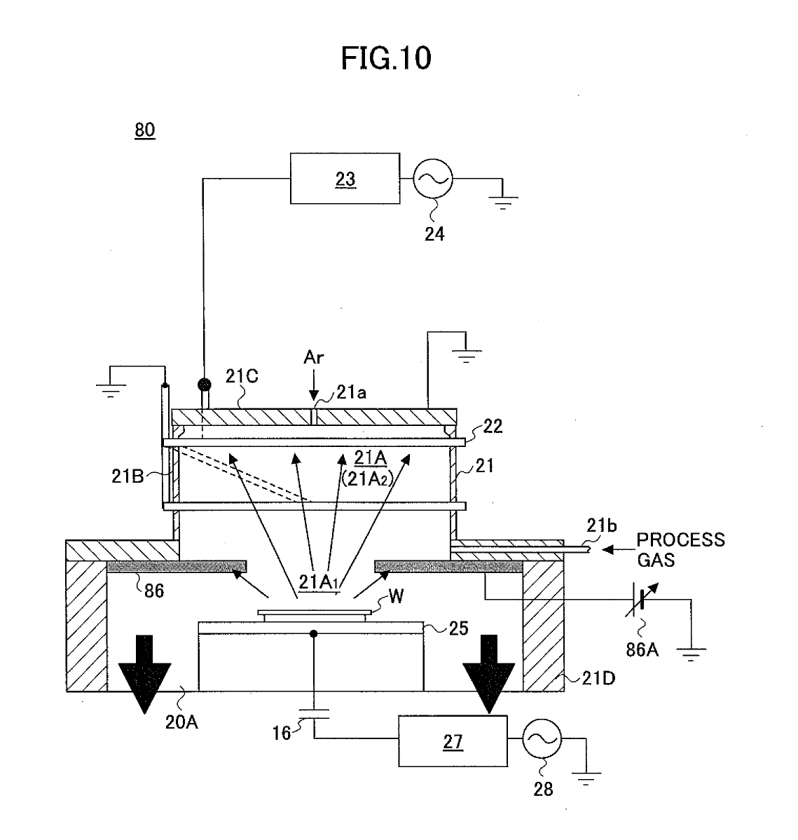

FIG. 10 shows the construction of a plasma etching apparatus 80 according to a fourth embodiment of the present invention, wherein those parts of FIG. 10 explained previously are designated by the same reference numerals and the description thereof will be omitted.

In the present embodiment, the shielding plate 46 of quartz or alumina of the plasma etching apparatus 40 of FIG. 4 is replaced with a metal shielding plate 86.

In the case such a metal shielding plate 86 is provided inside the processing vessel 21, plasma formation in the processing vessel 21 is influenced by the potential of such a metal shielding plate 86.

Thus, with the plasma etching apparatus 80 of FIG. 10, there is provided a voltage control circuit 86A in electrical connection to the metal shielding plate 86 for controlling the potential of the metal shielding plate 86.

With such a construction, it becomes possible to control the deposition of the sputter particles to the inner wall of the processing vessel 21 without exerting substantial influence on the plasma formation in the processing vessel 21.

While the present invention has been explained with regard to the ICP plasma etching apparatus, the present invention is not limited to such a particular plasma etching apparatus but is applicable also to other high density plasma etching apparatuses such as ECR apparatus, or the like.

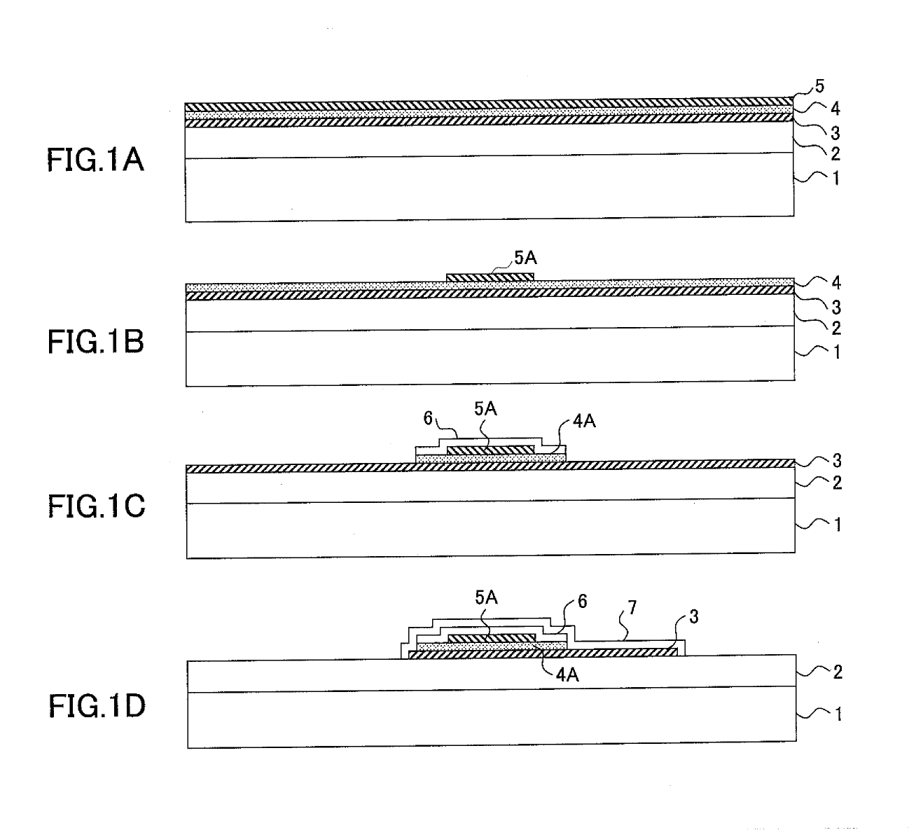

By using the plasma etching apparatus of the present invention, it becomes possible to form a ferroelectric capacitor such as the one explained previously with reference to FIGS. 1A-1D. Thereby, by using the plasma etching apparatus of the present invention, it becomes possible to achieve patterning not only for the PZT film formed on a substrate but also other ferroelectric films such as a PLZT ((Pb,La)(Zr,Ti)O₃) film, an SBT (SrBi₂(Ta,Nb)₂O₉) film, or the like, a high-K dielectric film such as BST (BaSrTiO₃) film, an STO (SrTiO₃) film, a HfO₂ film, or the like, a metal oxide film containing a metallic element such as Al, Ti, or the like, or a metal film or compound film containing any of Pt, Ir, Ru, Co, Fe, Sm, and Ni, with high efficiency and high yield.

Further, the present invention is not limited to the embodiments described heretofore, but various variations and modifications may be made without departing from the scope of the invention.

1.-3. (canceled)

4. A substrate processing apparatus, comprising:
a processing vessel evacuated by an evacuation system and including therein a stage for holding thereon a substrate to be processed, said processing vessel defining therein a processing space;
a processing gas supply path that introduces an etching gas into said processing vessel;
a plasma source that forms plasma in said processing space; and
a high-frequency source connected to said stage,
said processing vessel including therein a shielding plate dividing said processing space into a first processing space part including a surface of said substrate to be processed and a second processing space part corresponding to a remaining part of said processing space,
wherein said shielding plate is formed with an opening having a size larger than a size of said substrate to be processed,
wherein said shielding plate has a sloped surface sloped to a substrate to be processed in a part thereof.

5. The substrate processing apparatus as claimed in claim 4, wherein said sloped surface is formed along said opening in a manner to incline in an upper direction toward a center of said opening, and wherein said sloped surface defined said opening.

6. The substrate processing apparatus as claimed in claim 5, wherein said shielding plate includes an extension part extending generally perpendicularly to a surface of said substrate to be processed at an edge part of said sloped surface defining said opening.

7.-12. (canceled)

13. A method for fabricating a semiconductor device including a step of pattering a film formed on a substrate, comprising the steps of:
holding said substrate on a stage inside a processing vessel as a substrate to be processed, said processing vessel defining a processing space and evacuated by an evacuation system;
etching said film by introducing an etching gas into said processing vessel and by forming plasma in said processing space; and
capturing particles sputtered from said substrate to be processed during said step of etching by a shielding plate provided in said processing vessel so as to divide said processing space into a first processing space part including a surface of said substrate to be processed and a second processing space part including a remaining part of said processing space, said shielding plate being formed with an opening having a size larger than a size of said substrate to be processed.

14. The method as claimed in claim 13, wherein said substrate is held generally horizontally on said stage.

15. The method as claimed in claim 13, wherein said film comprises a ferroelectric film.

16. The method as claimed in claim 13, wherein said film comprises a metal oxide film containing any of Al and Ti.

17. The method as claimed in claim 13, wherein said film contains any of Pt, Ir, Ru, Co, Fe, Sm and Ni.
